(19) United States
(12) Patent Application Publication
(10) Pub. No.: US 2026/0136494 A1
(43) Pub. Date: May 14, 2026

(54) LIQUID COOLING SERVER RACK

(71) Applicant: Super Micro Computer, Inc., San Jose, CA (US)

(72) Inventors: Shih-Chin HUANG, Taipei (TW); Shih-Wei HUANG, Taipei (TW)

(21) Appl. No.: 19/373,384

(22) Filed: Oct. 29, 2025

(30) Foreign Application Priority Data
Nov. 12, 2024 (TW) 113143380

(51) Int. Cl. H05K 7/20; H05K 7/14; H05K 7/18

(52) U.S. Cl. CPC H05K 7/20272; H05K 7/1491; H05K 7/1492; H05K 7/18; H05K 7/20772

(57) ABSTRACT

A liquid cooling server rack having a cabinet, a server, a coolant distribution manifold (CDM), a power distribution unit (PDU), a plurality of liquid pipes, and an electric cable is disclosed. The server is arranged in the cabinet to form a first space, a second space, and two side spaces with the cabinet. The CDM and the PDU are arranged on the cabinet and located in the side spaces. Two ends of the liquid pipes are respectively connected to the CDU and a side of the server adjacent to the first space. Two ends of the electric cable are respectively connected to the PDM and a side of the server adjacent to the second space. Therefore, the liquid and the electric are separated to meet safety regulations, the cooling efficiency of the electric cable is improved, and the liquid pipes and the electric cable are conveniently organized and maintained.

### CROSS-REFERENCE TO RELATED APPLICATION

This application claims the benefit of Taiwan Patent Application No. 113143380 filed on November 12, 2024. The entire contents of the above-noted Taiwan patent application are incorporated herein by reference in its entirety.

### BACKGROUND

### Technical Field

The present disclosure relates to a liquid cooling server rack.

### Description Of Related Art

With the rapid development of electronic technology and artificial intelligence (AI), servers are widely used in high-density, high-power, and high-performance configurations to provide fast and powerful computing capabilities. When needed, a plurality of servers may be placed in a single rack. As server performance improves, heat generated during operation increases accordingly, such that most rack configurations have gradually adopted liquid cooling to dissipate heat. Such racks are equipped with coolant distribution manifolds (CDM) to distribute coolant to the servers, and power distribution units (PDU) to provide electricity.

The dimensions of the racks are standardized and liquid cooling is becoming an increasingly popular option, and the CDMs and PDUs are often hung behind the servers in the rack. Therefore, a plurality of electric cables and a plurality of liquid pipes are also located behind the servers, resulting in poor heat dissipation efficiency for the electric cables, safety concerns from the co-location of liquid and electricity, and difficulty maintaining the large quantity of electric cables and liquid pipes.

In view of the above, the invention seeks to overcome the aforementioned drawbacks associated with the current technology and aims to provide an effective solution through extensive research along with utilization of academic principles and knowledge.

### SUMMARY

The primary objective of the present invention is to effectively separate liquid and electricity, so as to comply with safety regulations, improve cooling efficiency of the electric cable, and conveniently organize and maintain the liquid pipes and the electric cable.

To accomplish the aforementioned objective, the present invention provides a liquid cooling server rack having a cabinet, a server, at least one coolant distribution manifold (CDM), at least one power distribution Unit (PDU), a plurality of liquid pipes, and an electric cable. The server is arranged in the cabinet. Four sides of the server and the cabinet together form a first space, a second space, and a pair of side spaces. The first space and the second space are located on two opposite sides of the server. Each of the side spaces is located on the other two opposite sides of the server. The CDM is arranged in the cabinet and correspondingly located in one of the side spaces. The PDU is arranged in the cabinet and correspondingly located in one of the side spaces. Each of the liquid pipes is configured to correspond to the first space. The two ends of each of the liquid pipes are respectively connected to the CDU and a side of the server adjacent to the first space. The electric cable is configured to correspond to the second space. The two ends of the electric cable are respectively connected to the PDM and a side of the server adjacent to the second space.

Another aspect of the present invention provides that the CDM is located in the corresponding side space and does not exceed beyond the side of the server connected to each of the liquid pipes, and the PDU is located in the corresponding side space and does not extend beyond the side of the server connected to electric cable.

Another aspect of the present invention further discloses a plurality of carrying brackets. Each of the carrying brackets is connected to the cabinet located in each of corresponding side spaces. The CDM and the PDU are respectively arranged on each of the carrying brackets.

Another aspect of the present invention provides that in each of the carrying brackets, the carrying bracket includes a fixing plate, a connecting plate, and a shielding plate, the fixing plate is connected to the cabinet, the connecting plate is connected between the fixing plate and the shielding plate, the CDM or the PDU is arranged on the connecting plate, the shielding plate is between the server and one of the CDM and the PDU.

Another aspect of the present invention provides that in each of the carrying brackets, the fixing plate and the shielding plate are respectively located on two opposite sides of the connecting plate.

Another aspect of the present invention further discloses a plurality of expansion positioning members, the CDM and the PDU are respectively equipped with at least one expansion positioning member, each of the expansion positioning members includes a hanging block, each of the carrying brackets has a plurality of hanging holes, each of the hanging blocks is hung in each of the hanging holes to make the CDM and the PDU be arranged on each of the carrying brackets.

Another aspect of the present invention provides that each of the hanging holes is reverse gourd shape, each of the hanging blocks is expanded and extended away from the corresponding CDM or the corresponding PDU.

Another aspect of the present invention provides that in each of the expansion positioning members, the expansion positioning member further includes a mounting plate, the mounting plate is arranged on the corresponding CDM or the corresponding PDU, the hanging block is extended from the mounting plate along a direction away from the corresponding CDM or the corresponding PDU.

Another aspect of the present invention discloses two CDM, each of the CDMs is configured to be corresponding to each of the side spaces, two ends of each of the liquid pipes are respectively connected to one of the CDMs and the side of the server adjacent to the first space.

Another aspect of the present invention discloses two PDU, each of the PDUs is configured to be corresponding to each of the side spaces.

In the liquid cooling server rack of the present invention, the CDM and the PDU are arranged in the side spaces, the liquid pipes are configured to be corresponding to the first space and connected to the CDM and the side of the sever corresponding to the first space, the electric cable is configured to be corresponding to the second space and connected to the PDU and the side of the sever corresponding to the second space, so as to effectively separate liquid and electricity to comply with safety regulations, improve the cooling efficiency of the electric cable, and conveniently organize and maintain the liquid pipes and the electric cable.

### BRIEF DESCRIPTION OF THE DRAWINGS

FIG. 1 is a perspective appearance view of the present disclosure;

FIG. 2 is another perspective appearance view of the present disclosure;

FIG. 3 is an exploded view of the present disclosure

FIG. 4 is a cross-sectional top view of the present disclosure; and

FIG. 5 is a partial exploded view of the carrying brackets and the CDM of the present disclosure.

### DETAILED DESCRIPTION

The terms for indicating positions and the location relation, for example “front”, “rear”, “left”, “right”, “front end”, “rear end”, “distal end”, “longitudinal direction”, “lateral direction”, “vertical direction”, “top” and “bottom”, are based on the positions and the location relation disclosed in the drawings. The terms are only used for describing the present invention and are not used to indicate or imply the specific location of the device or the components or the specific structure and operation in certain location. Thus, these terms as used in this disclosure are not intended to be limiting.

For example, the terms of “first”, “second”, “third”, “forth” and “fifth” are used for illustrating each unit, component, area, layer and/or part. The component, the unit, the area, the layer and/or the part are not limited by the terms. These terms are only used to differentiate the element, the assembly, the area, the layer, or the part. Unless clearly indicated according to the whole specification, terms such as “the first”, “the second”, “the third”, “the fourth” and “the fifth” are not used to imply the order or sequence.

As used herein and unless otherwise defined, the terms "substantially" and "approximately" are used to describe small changes. When used in connection with an event or situation, the terms may include the precise moment at which the event or situation occurs, as well as the event or situation occurring to a close approximation. For example, when combined with a numerical value, the terms may include a range of variation equal to or less than ±5% of the numerical value, such as equal to or less than ±4%, equal to or less than ±3%, equal to or less than ±2%, equal to or less than ±1%, equal to or less than ±0.5%, equal to or less than ±0.1%, or equal to or less than ±0.05%.

The technical contents of the present disclosure will become apparent with the detailed description of embodiments and the accompanied drawings as follows. However, the accompanying drawings are for illustrative purposes only and shall not be used to restrict the scope of the present disclosure.

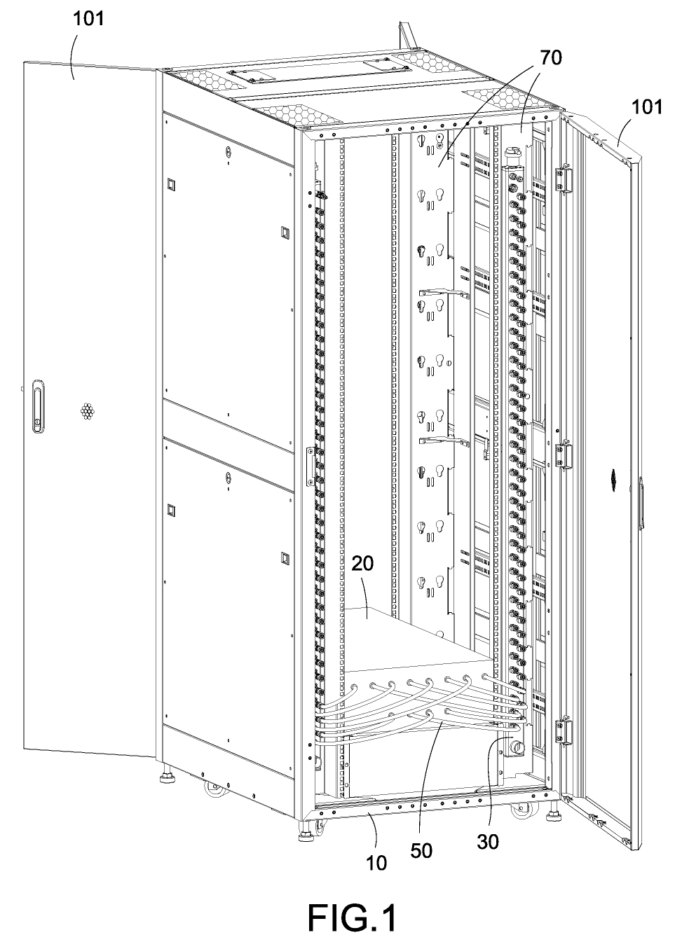

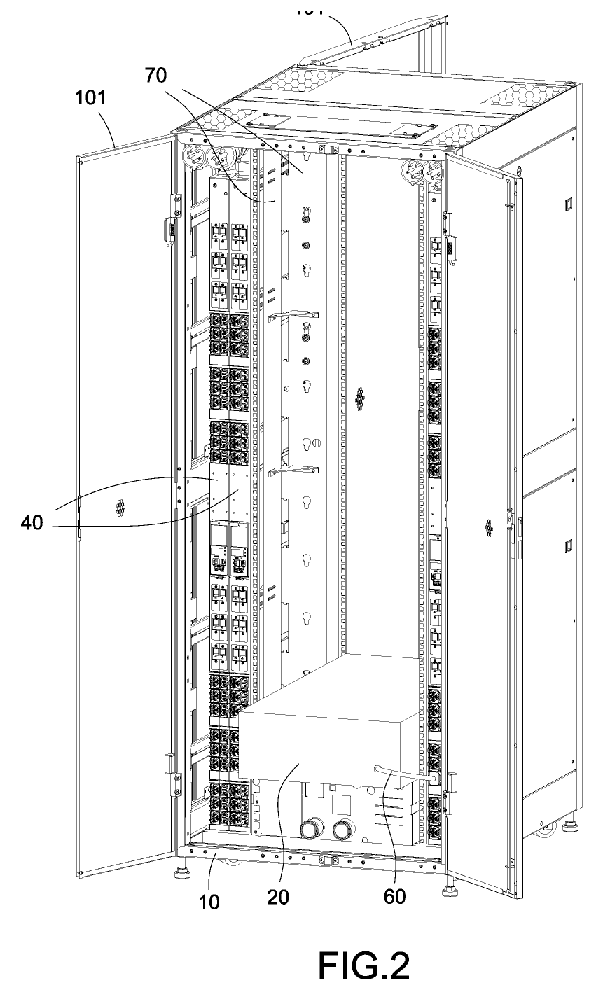

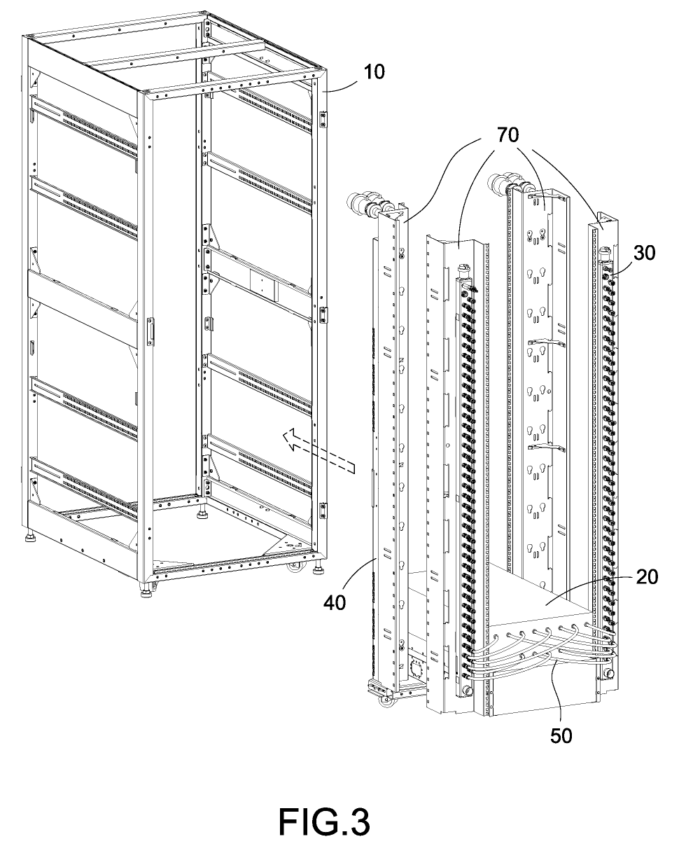

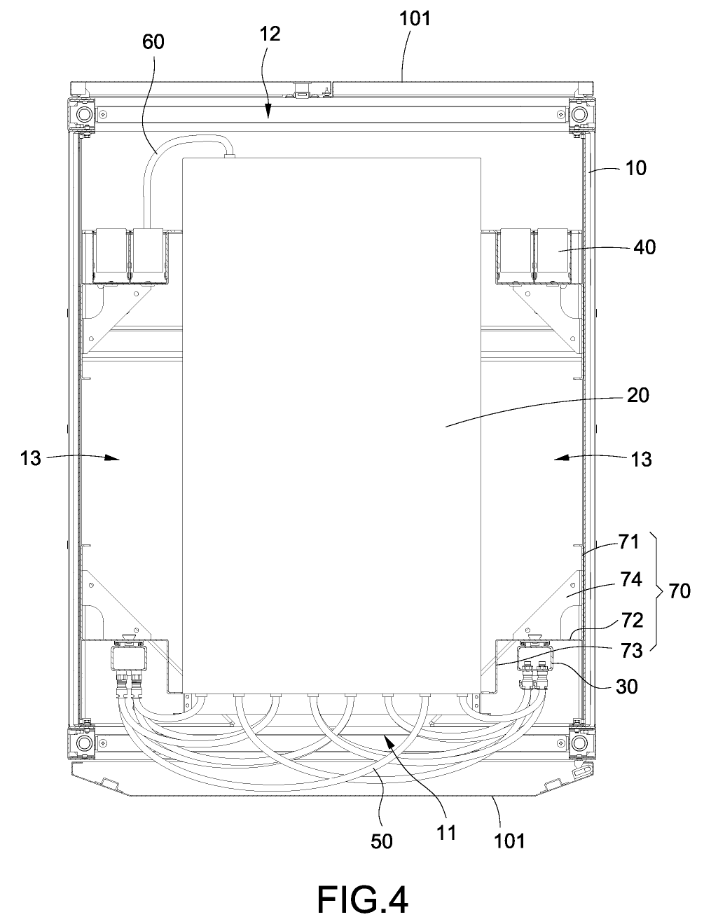

The present disclosure provides a liquid cooling server rack. Please refer to FIG. 1, FIG. 2, FIG. 3, and FIG. 4, the liquid cooling server rack of the present disclosure mainly includes a cabinet 10, at least one server 20, at least one coolant distribution manifold (CDM) 30, at least one power distribution Unit (PDU) 40, a plurality of liquid pipes 50, and at least one electric cable 60. It should be noted that in order to simplify illustration and for the convenience of description, the detail description and the figures of the present disclosure merely show and describe one server 20 and one electric cable 60. However, the liquid cooling server rack of the present disclosure is not limited to the embodiment including only one server 20 and one electric cable 60. The number of the server 20 and the number of the electric cable 60 may be increased according to different needs base on the detailed description and figures.

The cabinet 10 is a frame structure formed by a plurality of frames (not labeled in figures) connected to each other. In detail, the cabinet 10 of the embodiment is a rectangular body formed by eight frames connected to each other, but the present disclosure is not limited to this embodiment, the shape of the cabinet 10 may be modified according to different needs. In the embodiment, a plurality of reinforcement ribs (not labeled in figures) is connected between each two of the frames of the cabinet 10 to strengthen the overall structural strength of the cabinet 10. However, a front side of the cabinet 10 and a rear side of the cabinet 10 do not arrange any reinforcement ribs, so as to facilitate user to mount or repair components inside the cabinet 10 from the front side or the rear side. In addition, a plurality of partitions (not labeled in figures) is connected between each two of a left side of the cabinet 10, a right side of the cabinet 10, a top side of the cabinet 10, and a bottom side of the cabinet 10 to close the left side, right, top, and bottom sides of the cabinet 10, and two doors 101 are respectively pivoted to the front side and the rear side of the cabinet 10, but the present disclosure is not limited to this embodiment.

The server 20 is arranged in the cabinet 10. In detail, the server 20 may be placed on a track, a layer plate, or a supporting bracket inside the cabinet 10, the present disclosure does not limit this. Four sides of the server 20 (that is a front side, a rear side, a left side, and a right side) and the cabinet 10 together form a first space 11, a second space 12, and a pair of side spaces 13. In detail, the first space 11 and the second space 12 are located on two opposite sides of the server 20 (the front side and the rear side), each of the side spaces 13 are located on other two opposite sides of the server 20 (the left side and the right side).

The CDM 30 is used for distributing a coolant to a heat source of the server 20 in the cabinet 10, so as to improve the overall liquid cooling efficiency, save space configuration, and facilitate wiring and cable management. Since the specific structure and the operating principle of the CDM 30 are well known in this field, they are not described here. The CDM 30 is arranged in the cabinet 10 and correspondingly located in one of the side spaces 13.

The PDU 40 is used for distributing a power from a power supply to the server 20 and other electronic devices in the cabinet 10 for use. Since the specific structure and the operating principle of the PDU 40 are well known in this field, they are not described here. The PDU 40 is arranged in the cabinet 10 and correspondingly located in one of the side spaces 13.

Each of the liquid pipes 50 is configured to be corresponding to the first space 11, that is each of the liquid pipes 50 is approximately located in the first space 11 and covered by the door 101. In detail, two ends of each of the liquid pipes 50 are respectively connected to the CDU 30 and a side of the server 20 adjacent to the first space 11, so as to distribute the coolant inside the CDU 30 to the heat source of the server 20.

The electric cable 60 is configured to be corresponding to the second space, that is the electric cable 60 is approximately located in the second space 12 and covered by the door 101. In detail, two ends of the electric cable 60 are respectively connected to the PDM 40 and a side of the server 20 adjacent to the second space 12, so as to transfer the power to the server 20.

Therefore, since the liquid pipes 50 and the electric cable 60 are respectively located in the first space 11 and the second space 12 on opposite sides of the cabinet 10, such that the liquid pipes 50 and the electric cable 60 may be separated to comply with safety regulations. In addition, since the liquid pipes 50 and the electric cable 60 are respectively arranged on two opposite sides of the server 20, the cooling efficiency of the electric cable 60 may be improved, and the liquid pipes 50 and the electric cable 60 would not be arranged together to cause interference such that user may facilitate to organize and maintain the liquid pipes 50 and the electric cable 60. It is worth to noting that since the figures of the present disclosure merely show one server 20 and one electric cable 60, the present disclosure may install a plurality of the servers 20 and a corresponding number of electric cables 60 in the actual application, and two ends of each of the electric cables 60 are respectively connected to the PDU 40 and the side of the server 20 corresponding to the second space 12 such that all of the electric cables 60 are still located in the second space 12.

Details are provided as follows. Since the pipe liquid pipes 50 and the electric cable 60 have a certain degree of bending flexibility, even if the two ends of each of the pipe liquid pipes 50 or the two ends of the electric cable 60 are on the same straight line, they may still protrude from the front and rear sides of the server 20 due to the bending flexibility thereof, such that a front-rear depth of the cabinet 10 is increased to affect the space configuration of the liquid cooling server rack. Therefore, the CDM 30 of the embodiment is located in the corresponding side space 13 and does not exceed the side of the server 20 connected to each of the liquid pipes 50, and the PDU 40 is located in the corresponding side space 13 and does not exceed the side of the server 20 connected to the electric cable 60, such that the liquid pipes 50 and the electric cable 60 may reduce the influence of their bending flexibility as much as possible to efficiently decrease the front-rear depth of the cabinet 10 to facilitate the space configuration of the liquid cooling server rack, but the present disclosure is not limited to this embodiment.

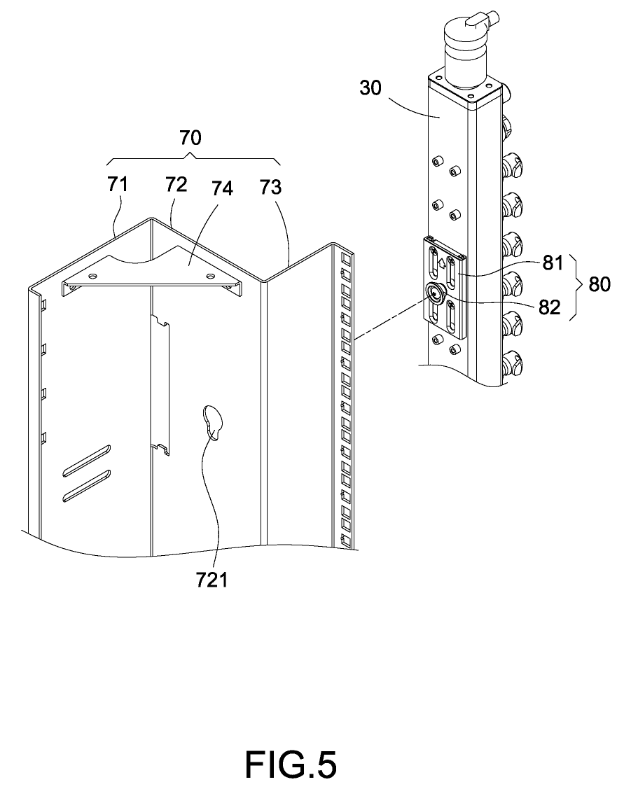

Please refer again to FIG. 3, FIG. 4, and FIG. 5, the liquid cooling server rack of the present disclosure further includes a plurality of carrying brackets 70. Each of the carrying brackets 70 is connected in the cabinet 10 and correspondingly located in each of the side spaces 13. The CDM 30 and the PDU 40 are respectively arranged on the carrying brackets 70. Each of the carrying brackets 70 includes a fixing plate 71, a connecting plate 72, a shielding plate 73, and a reinforcement plate 74. In each of the carrying brackets 70, the fixing plate 71 is connected to the cabinet 10 by welding or screwing, the connecting plate 72 is connected between the fixing plate 71 and the shielding plate 73 for mounting the CDM 30 or the PDU 40, the shielding plate 73 is between the server 20 and one of the CDM 30 and the PDU 40, and the reinforcement plate 74 is connected between the fixing plate 71 and the connecting plate 72 to strengthen the structural strength between them. Therefore, the carrying brackets 70 may be arranged on different locations of the side spaces 13 according to different needs to adjust the positions of the CDM 30 and the PDU 40. The shielding plate 73 is blocked between the server 20 and one of the CDM 30 and the PDU 40, so as to reduce the impact of electromagnetic waves from the PDU 40 on the server 20 and prevent the coolant from splashing directly on the server 20 when the CDM 30 leaks.

In the embodiment, the fixing plate 71 and the shielding plate 73 in each of the carrying brackets 70 are respectively located on two opposite sides of the connecting plate 72 such that a cross section of the carrying bracket 70 is lightning-shaped, but the present disclosure is not limited to this embodiment. Therefore, during mounting, the CDM 30 or the PDU 40 may be conveniently arranged on the corresponding carrying bracket 70 first, the CDM 30 or the PDU 40 and the corresponding carrying bracket 70 are then together arranged in the cabinet 10.

In addition, the liquid cooling server rack of the present disclosure further includes a plurality of expansion positioning members 80. In the embodiment, the CDM 30 and the PDU 40 are respectively equipped with at least one expansion positioning member 80, but the present disclosure is not limited to this embodiment. Each of the expansion positioning members 80 includes a mounting plate 81 and a hanging block 82. In each of the expansion positioning members 80, the mounting plate 81 is arranged on a back side of the corresponding CDM 30 or the corresponding PDU 40 (that is a side opposite to the side connected the liquid pipe50 or the electric cable 60), the hanging block 82 is extended from the mounting plate 81 along a direction away from the corresponding CDM 30 or the corresponding PDU 40. The connecting plate 72 of each of the carrying brackets 70 has a plurality of hanging holes 721 defined along a vertical direction thereof. Each of the hanging blocks 82 on the CDM 30 or the PDU 40 is hung in two of the hanging holes 721 of the corresponding carrying brackets 70 to make the CDM 30 and the PDU 40 be arranged on the corresponding carrying bracket 70. In detail, each of the hanging holes 721 is reverse gourd shape, and each of the hanging blocks 82 is expanded and extended away from the corresponding CDM 30 or the corresponding PDU 40 to be trumpet-shaped. Therefore, user may penetrate the hanging blocks 82 through a big circle of the hanging holes 721 first, user then moves the hanging blocks 82 downward to hang in a small circle of the hanging holes 721 smaller than the big circle to avoid falling off, so as to efficiently simplify the installation process of the CDM 30 and the PDU 40 on the carrying brackets 70.

In the embodiment, a number of the CDM 30 is two, and each of the CDMs 30 is configured to be corresponding to each of the side spaces 13. Two ends of each of the liquid pipes 50 are respectively connected to one of the CDMs 30 and the side of the server 20 adjacent to the first space 11. One of the CDMs 30 is used for supplying the coolant to the server 20, the other one is used for retrieving the coolant flowing out from the server 20. In addition, a number of the PDU 40 is two, and each of the PDUs 40 is configured to be corresponding to each of the side spaces 13, so as to supply the electric cables 60 of the servers 20 for using.

In the liquid cooling server rack of the present disclosure, the CDM 30 and the PDU 40 are arranged in the side spaces 13, the liquid pipes 50 are configured to be corresponding to the first space 11 and connected to the CDM 30 and the side of the sever 20 corresponding to the first space 11, the electric cable 60 is configured to be corresponding to the second space 12 and connected to the PDU 40 and the side of the sever 20 corresponding to the second space 12, so as to effectively separate liquid and electricity to comply with safety regulations, improve the cooling efficiency of the electric cable 60, and conveniently organize and maintain the liquid pipes 50 and the electric cable 60.

It shall be understood that the present disclosure may have other types of embodiments, and a person with ordinary skills in the art of the technical field of the present disclosure may make various changes and modifications corresponding to the present disclosure without deviating the principle and substance of the present disclosure; however, such corresponding changes and modification shall be considered to be within the claimed scope of the present disclosure.

What is claimed is:

1. A liquid cooling server rack, comprising:
a cabinet;
a server, arranged in the cabinet, four sides of the server and the cabinet together forming a first space, a second space, and a pair of side spaces, the first space and the second space located on two opposite sides of the server, each of the side spaces located on other two opposite sides of the server;
at least one coolant distribution manifold (CDM), arranged in the cabinet and correspondingly located in one of the side spaces;
at least one power distribution Unit (PDU), arranged in the cabinet and correspondingly located in one of the side spaces;
a plurality of liquid pipes, configured to be corresponding to the first space, two ends of each of the liquid pipes respectively connected to the CDU and a side of the server adjacent to the first space; and
an electric cable, configured to be corresponding to the second space, two ends of the electric cable respectively connected to the PDM and a side of the server adjacent to the second space.

2. The liquid cooling server rack according to claim 1, wherein the CDM is located in the corresponding side space and does not exceed the side of the server connected to each of the liquid pipes, the PDU is located in the corresponding side space and does not exceed the side of the server connected to the electric cable.

3. The liquid cooling server rack according to claim 1, further comprising a plurality of carrying brackets, wherein each of the carrying brackets is connected to the cabinet and correspondingly located in each of the side spaces, the CDM and the PDU are respectively arranged on each of the carrying brackets.

4. The liquid cooling server rack according to claim 3, wherein in each of the carrying brackets, the carrying bracket comprises a fixing plate, a connecting plate, and a shielding plate, the fixing plate is connected to the cabinet, the connecting plate is connected between the fixing plate and the shielding plate, the CDM or the PDU is arranged on the connecting plate, the shielding plate is between the server and one of the CDM and the PDU.

5. The liquid cooling server rack according to claim 4, wherein in each of the carrying brackets, the fixing plate and the shielding plate are respectively located on two opposite sides of the connecting plate.

6. The liquid cooling server rack according to claim 3, further comprising a plurality of expansion positioning members, wherein the CDM and the PDU are respectively equipped with at least one expansion positioning member, each of the expansion positioning members comprises a hanging block, each of the carrying brackets comprises a plurality of hanging holes, each of the hanging blocks is hung in each of the hanging holes to make the CDM and the PDU be arranged on each of the carrying brackets.

7. The liquid cooling server rack according to claim 6, wherein each of the hanging holes is reverse gourd shape, each of the hanging blocks is expanded and extended away from the corresponding CDM or the corresponding PDU.

8. The liquid cooling server rack according to claim 6, wherein in each of the expansion positioning members, the expansion positioning member further comprises a mounting plate, the mounting plate is arranged on the corresponding CDM or the corresponding PDU, the hanging block is extended from the mounting plate along a direction away from the corresponding CDM or the corresponding PDU.

9. The liquid cooling server rack according to claim 1, wherein a number of the CDM is two, each of the CDMs is configured to be corresponding to each of the side spaces, two ends of each of the liquid pipes are respectively connected to one of the CDMs and the side of the server adjacent to the first space.

10. The liquid cooling server rack according to claim 1, wherein a number of the PDU is two, each of the PDUs is configured to be corresponding to each of the side spaces.
